(19) United States
(12) Patent Application Publication
(10) Pub. No.: US 2008/0200039 A1
(43) Pub. Date: Aug. 21, 2008

(54) NITRIDATION PROCESS

(75) Inventors: Wenshen Li, SINGAPORE (SG); Chien-Kee Pang, SINGAPORE (SG); Ching-Yang Wen, SINGAPORE (SG); Teng-Ming Hoong, SINGAPORE (SG)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/675,802

(22) Filed: Feb. 16, 2007

(51) Int. Cl. H01L 21/31

(52) U.S. Cl. 438/776; 257/E21.24

(57) ABSTRACT

The invention is directed to a nitridation process for a wafer. The nitridation process comprises steps of disposing the wafer on a top surface of a chuck in a nitridation process tool, wherein a plurality of concentric pipe coils is disposed close to the bottom surface of the chuck. Then, the chuck is heated and the chuck is regionally cooling down by applying a coolant into the concentric pipe coils, wherein the flow rates of the coolant in the concentric pipe coils are different from each other. Furthermore, a plasma nitridation process is performed on the wafer.

### BACKGROUND OF THE INVENTION

1. Field of Invention

The present invention relates to a semiconductor process. More particularly, the present invention relates to a nitridation process.

2. Description of Related Art

When the integration for semiconductor device in integrated circuit is getting larger and larger, it is also requited to have supper-thin gate dielectric layer with high dielectric constant and low leakage current. When the size of a metal oxide semiconductor (MOS) transistor is less than 100 nm, the dielectric constant usually needs to be greater than 7. The material with higher dielectric constant can improve isolation effect. However, the gate dielectric layer in MOS transistor is formed by silicon oxide, and the dielectric constant for the silicon oxide is about 3.9. The silicon oxide is therefore not suitable for use as the dielectric layer in the MOS device with more and more reduced size. The conventional technology usually uses the nitridation process to dope the dielectric layer of silicon oxide, so as to increase the dielectric constant.

One of the widely used nitridation process is the plasma nitridation process. The plasma nitridation process uses the method of ion bombardment to dope the nitrogen atoms into a material layer. It should be noticed that the nitrogen dose density in a material layer is sensitive to the temperature variation. That is, with increasing the environment temperature of about 1 centigrade over a particular region, the nitrogen dose density increase of about 10^{13.} However, the operation temperature of the plasma over the wafer in the nitridation process is not consistent. Therefore, the nitrogen dose density in the material layer over the entire wafer is not uniformly distributed. Hence, the electric performance of the dies from the same wafer is different.

### SUMMARY OF THE INVENTION

Accordingly, at least one objective of the present invention is to provide a nitridation process capable of regionally adjusting the wafer temperature through the chuck to compensate the temperature inconsistent issue caused by the plasma.

At least another objective of the present invention is to provide a method for nitridizing a material layer capable of regionally uniform the nitrogen dose density in the material layer over the entire wafer.

To achieve these and other advantages and in accordance with the purpose of the invention, as embodied and broadly described herein, the invention provides a nitridation process for a wafer. The nitridation process comprises steps of disposing the wafer on a top surface of a chuck in a nitridation process tool, wherein a plurality of concentric pipe coils is disposed close to the bottom surface of the chuck. Then, the chuck is heated and the chuck is regionally cooling down by applying a coolant into the concentric pipe coils, wherein the flow rates of the coolant in the concentric pipe coils are different from each other. Furthermore, a plasma nitridation process is performed on the wafer.

As for the nitridation process described above according to the embodiment of the present invention, the flow rate of the coolant in each of the concentric pipe coils is determined according to a nitridation profile presented by the nitridation process tool.

As for the nitridation process described above according to the embodiment of the present invention, the nitridation profile is a nitrogen dose distribution as a function of the distance away from a wafer center.

As for the nitridation process described above according to the embodiment of the present invention, in the nitridation profile, when a nitrogen dose density over a first region of the wafer is relatively high, the flow rate of the coolant in a first pipe coil above the first region is relatively high.

As for the nitridation process described above according to the embodiment of the present invention, in the nitridation profile, when a nitrogen dose density over a second region of the wafer is relatively low, the flow rate of the coolant in a first pipe coil above the first region is relatively low.

As for the nitridation process described above according to the embodiment of the present invention, the coolant is selected from a group consisting of water, helium, nitrogen and refrigeration agent.

As for the nitridation process described above according to the embodiment of the present invention, in the step of heating the chuck, the temperature of the chuck is set to be about 20˜80 centigrade.

The present invention also provides a method for nitridizing a material layer over a wafer carried by a chuck in a nitridation process tool, wherein the nitridation process tool presents a nitridation profile. The method comprises steps of regionally adjusting the temperature of the chuck according to the nitridation profile and performing a plasma nitridation process for nitridizing the material layer.

As for the method described above according to the embodiment of the present invention, the nitridation profile is a nitrogen dose distribution as a function of the distance away from a wafer center.

As for the method described above according to the embodiment of the present invention, the method of regionally adjusting the temperature of the chuck comprises steps of heating the chuck and applying a coolant into a plurality of concentric pipe coils disposed under the chuck, wherein the flow rates of the coolant in the concentric pipe coils are different from each other.

As for the method described above according to the embodiment of the present invention, in the nitridation profile, when a nitrogen dose density over a first region of the wafer is relatively high, the flow rate of the coolant in a first pipe coil above the first region is relatively high.

As for the method described above according to the embodiment of the present invention, in the nitridation profile, when a nitrogen dose density over a second region of the wafer is relatively low, the flow rate of the coolant in a first pipe coil above the first region is relatively low.

As for the method described above according to the embodiment of the present invention, the coolant is selected from a group consisting of water, helium, nitrogen and refrigeration agent.

As for the method described above according to the embodiment of the present invention, in the step of heating the chuck, the temperature of the chuck is set to be about 20˜80 centigrade.

In the present invention, since the wafer is conditioned, by regionally adjusting the temperature of the wafer through the chuck, to be at a situation which compensate the temperature inconsistent caused by plasma, the nitridation result is free from the temperature inconsistent issue cause by plasma. Hence, for a single wafer, the nitrogen dose density is consistent over the entire wafer area. Further, for the wafers in the same product line, the nitridation qualities of the target material layers or the wafers are uniform.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a nitrogen dose density-wafer graph showing a nitridation profile of a plasma nitridation process tool.

FIG. 1B is another nitrogen dose density-wafer graph showing a nitridation profile of another plasma nitridation process tool.

FIG. 2 is a schematic cross-sectional view showing a chuck with a regionally adjusting temperature system according to a preferred embodiment of the invention.

FIG. 3 is a top view of an up-side-down chuck with a regionally adjusting temperature system thereon according to the embodiment of the present invention.

FIG. 4 is a flow chart illustrating a nitridation process according to one embodiment of the present invention.

### DESCRIPTION OF THE PREFERRED EMBODIMENTS

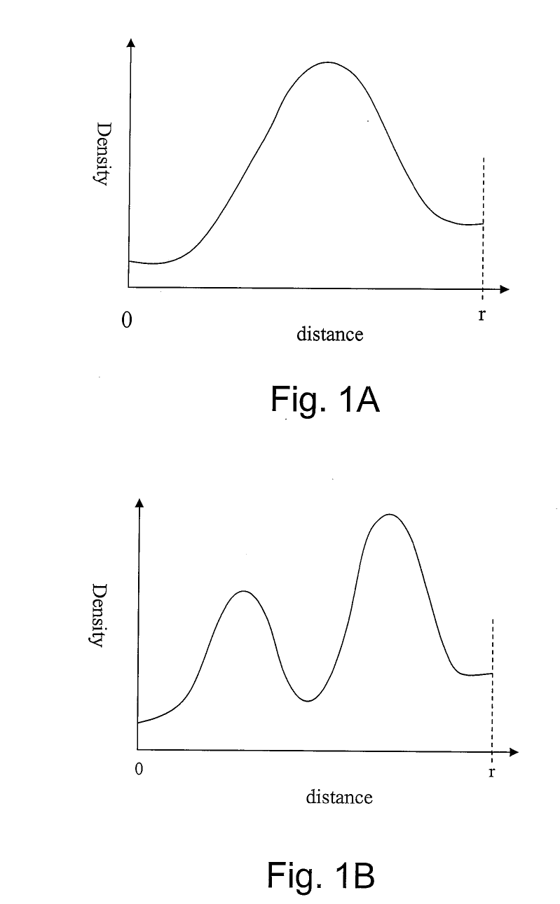

FIG. 1A is a nitrogen dose density-wafer graph showing a nitridation profile of a plasma nitridation process tool. FIG. 2 is a schematic cross-sectional view showing a chuck with a regionally adjusting temperature system according to a preferred embodiment of the invention. For a single plasma nitridation process tool, the characteristic nitridation profile represented by a nitrogen dose distribution as a function of the distance away from the wafer center. As shown in FIG. 1A, it is clear that, for the particular plasma nitridation process tool, the minimum nitrogen dose density happens at the wafer center and the maximum nitrogen dose density happens around middle the region between the wafer center and the wafer edge. On the other words, during the nitridation process is performed by the nitridation process tool, the temperature of the waters center region and the temperature of the wafer edge region is relatively low. Further, the temperature of the middle of the region between the wafer center and the wafer edge is relatively high during the same nitridation process. That is, the plasma temperature for nitridizing the material layer over the wafer covers the wafer with an inconsistent temperature over the entire wafer. As shown in 1B, for another plasma nitridation process tool, from the wafer center to the wafer edge, the nitrogen dose density undulate and the maximum nitrogen dose density is around the region close to the wafer edge.

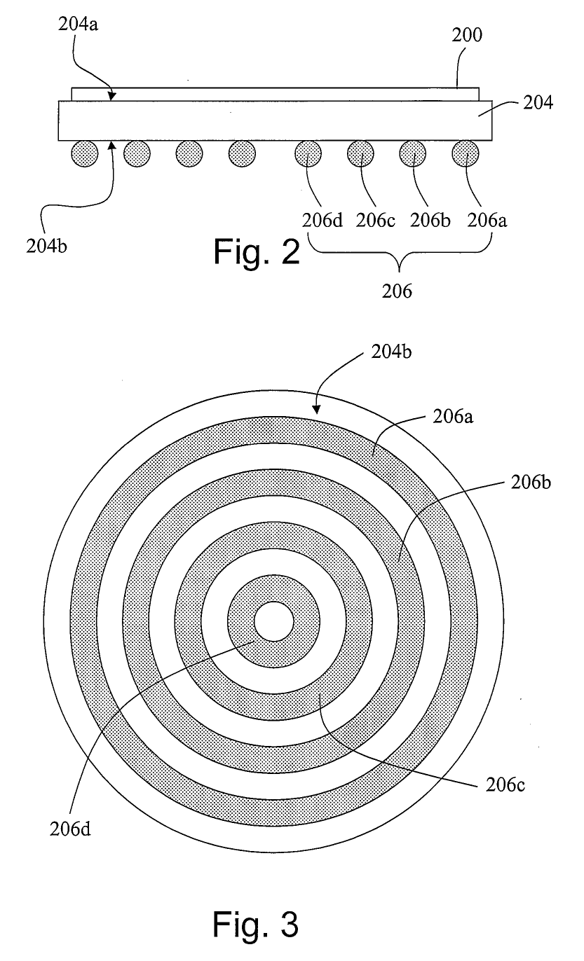

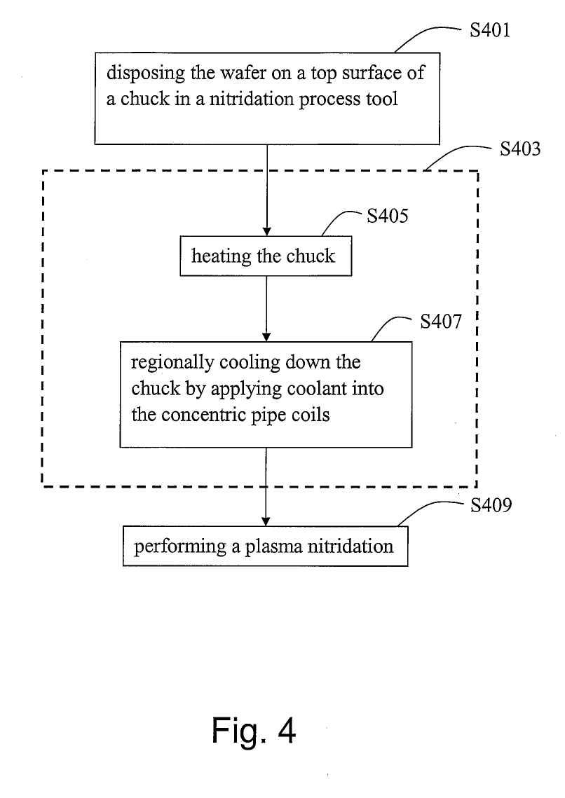

In order to uniform the nitrogen dose density in the material layer over the entire the wafer, the present invention provides a nitridation process capable of regionally adjusting the temperature of the wafer during the nitridation process is performed. FIG. 2 is a schematic cross-sectional view showing a chuck with a regionally adjusting temperature system according to a preferred embodiment of the invention. FIG. 3 is a top view of an up-side-down chuck with a regionally adjusting temperature system thereon according to the embodiment of the present invention. FIG. 4 is a flow chart illustrating a nitridation process according to one embodiment of the present invention. Referring to FIG. 2 together with FIG. 4, a wafer 200 is provided and is carried by a chuck 204 in a nitridation process tool 100 (step S401). That is, the wafer 200 is disposed on the top surface 204a of the chuck 204. The later performed nitridation process is used to nitridize the surface portion of the wafer 200 or a material layer (not shown) on the top of the wafer 200. The material layer can be, for example but not limited to, a dielectric layer for being a gate dielectric layer. The nitridation process tool can be, for example but not limited to, a plasma nitridation process tool.

Furthermore, as shown in FIG. 2 and FIG. 3, several concentric pipe coils 206 are disposed under the chuck 204 can close to the bottom surface 204b of the chuck 204. Each of the concentric pipe coils 206 further comprises at least one fluid inlet (not shown) and at least one fluid out let (not shown). In this embodiment, there are four concentric pipe coils 206 (206a, 206b, 206c and 206d). However, the number of the concentric pipe coils 206 in the present invention is not limited to be 4.

In the step S403, the temperature of the wafer 200 is regionally adjusted by regionally adjusting the temperature of the chuck 204 according to the nitridation profile of the nitridation process tool 100. The method for regionally adjusting the temperature of the chuck 204 in the step S403 can be accomplished by heating the chuck 204 (step S405) and then applying a coolant into the concentric pipe coils with different flow rates respectively to regionally cooling down the chuck 204 (step S407). The coolant can be, for example a fluid, and can be selected from a group consisting of water, helium, nitrogen and refrigeration agent. Moreover, the temperature of the chuck is set to be about 20˜80 centigrade. It should be noticed that the flow rate of the coolant in each of the concentric pipe coils 206 is determined according to the nitridation profile of the nitridation process tool 100. It should be noticed that the cooling efficiency of the concentric pipe coil with a relatively low coolant flow rate is much poor than the cooling efficiency of the concentric pipe coil with a relatively high coolant flow rate.

For example, as the nitridation profile shown in FIG. 1 presents the nitridation behavior of the nitridation process tool 100, the flow rates in the concentric pipe coils 206d, and 206a around the wafer center region and the wafer edge region are lower than the flow rates in the concentric pipe coils 206c, and 206b around the middle region between the wafer center and the wafer edge in order to cool down the chuck 204 with different degree in different regions. Accordingly, the inconsistent temperature over the entire wafer due to the plasma with inconsistent temperature over the entire wafer can be compensated by the chuck 204 being regionally adjusted in temperature during the nitridation process is performed.

As shown in FIG. 4, as the wafer temperature is regionally adjusted through the chuck 204, a nitridation process, such as plasma nitridation process, is performed (step S409). Even though the plasma generated by the nitridation process tool 100 still has the issue that the plasma is temperature inconsistent over the entire wafer, the nitridation result is free from the temperature inconsistent issue since the wafer 200 is conditioned, by regionally adjusting the temperature of the wafer through the chuck 204, to be at a situation which compensate the temperature inconsistent caused by plasma. Hence, for a single wafer, the nitrogen dose density is consistent over the entire wafer area. Further, for the wafers in the, same product line, the nitridation qualities of the target material layers or the wafers are uniform.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A nitridation process for a wafer, the nitridation process comprising:
disposing the wafer on a top surface of a chuck in a nitridation process tool, wherein a plurality of concentric pipe coils is disposed close to the bottom surface of the chuck;
heating the chuck;
regionally cooling down the chuck by applying a coolant into the concentric pipe coils, wherein the flow rates of the coolant in the concentric pipe coils are different from each other; and
performing a plasma nitridation process on the wafer.

2. The nitridation process of claim 1, wherein the flow rate of the coolant in each of the concentric pipe coils is determined according to a nitridation profile presented by the nitridation process tool.

3. The nitridation process of claim 2, wherein the nitridation profile is a nitrogen dose distribution as a function of the distance away from a wafer center.

4. The nitridation process of claim 2, wherein, in the nitridation profile, when a nitrogen dose density over a first region of the wafer is relatively high, the flow rate of the coolant in a first pipe coil above the first region is relatively high.

5. The nitridation process of claim 2, wherein, in the nitridation profile, when a nitrogen dose density over a second region of the wafer is relatively low, the flow rate of the coolant in a first pipe coil above the first region is relatively low.

6. The nitridation process of claim 1, wherein the coolant is selected from a group consisting of water, helium, nitrogen and refrigeration agent.

7. The nitridation process of claim 1, wherein, in the step of heating the chuck, the temperature of the chuck is set to be about 20˜80 centigrade.

8. A method for nitridizing a material layer over a wafer carried by a chuck in a nitridation process tool, wherein the nitridation process tool presents a nitridation profile, the method comprising:
regionally adjusting the temperature of the chuck according to the nitridation profile; and
performing a plasma nitridation process for nitridizing the material layer.

9. The method of claim 8, wherein the nitridation profile is a nitrogen dose distribution as a function of the distance away from a wafer center.

10. The method of claim 8, wherein the method of regionally adjusting the temperature of the chuck comprises steps of:
heating the chuck; and
applying a coolant into a plurality of concentric pipe coils disposed under the chuck, wherein the flow rates of the coolant in the concentric pipe coils are different from each other.

11. The method of claim 10, wherein, in the nitridation profile, when a nitrogen dose density over a first region of the wafer is relatively high, the flow rate of the coolant in a first pipe coil above the first region is relatively high.

12. The method of claim 10, wherein, in the nitridation profile, when a nitrogen dose density over a second region of the wafer is relatively low, the flow rate of the coolant in a first pipe coil above the first region is relatively low.

13. The method of claim 10, wherein the coolant is selected from a group consisting of water, helium, nitrogen and refrigeration agent.

14. The method of claim 10, wherein, in the step of heating the chuck, the temperature of the chuck is set to be about 20˜80 centigrade.
